(19) United States
(12) Patent Application Publication
(10) Pub. No.: US 2014/0301133 A1
(43) Pub. Date: Oct. 9, 2014

(54) METHOD AND SYSTEM FOR A HIGH-DENSITY, LOW-COST, CMOS COMPATIBLE MEMORY

(71) Applicant: MaxLinear, Inc., Carlsbad, CA (US)

(72) Inventors: Kimihiko Imura, San Diego, CA (US); Jianping Yang, Carlsbad, CA (US)

(73) Assignee: MaxLinear, Inc., Carlsbad, CA (US)

(21) Appl. No.: 14/244,327

(22) Filed: Apr. 3, 2014

Related U.S. Application Data
(60) Provisional application No. 61/807,823, filed on Apr. 3, 2013.

(51) Int. Cl. G11C 11/24

(52) U.S. Cl. CPC G11C 11/24
USPC 365/149

(57) ABSTRACT

Methods and systems for a high-density, low-cost, CMOS compatible memory may comprise a memory cell on a chip, the memory cell comprising: a plurality of capacitor/switch pairs, where for each pair comprising a switch and a capacitor, a source terminal of the switch is coupled to a gate terminal of the capacitor. The memory cell may also comprise a reset transistor, a biasing circuit, and a source follower. A drain terminal of each switch may be coupled to a floating node that couples a source terminal of the reset transistor and a gate terminal of the source follower. Drain and source terminals of each of the switches of the plurality of capacitor/switch pairs may be coupled to ground. A number of the plurality of capacitor/switch pairs may indicate a number of bits in the memory. The biasing circuit may comprise a current mirror. A bit-line for the memory cell may be coupled to a source terminal of the source follower. The bit-line may comprise a metal trace.

### CROSS-REFERENCE TO RELATED APPLICATIONS/INCORPORATION BY REFERENCE

This application makes reference to and claims priority to U.S. Provisional Application Ser. No. 61/807,823 filed on Apr. 3, 2013. The above identified application is hereby incorporated herein by reference in its entirety.

### FIELD

Certain embodiments of the invention relate to semiconductor devices. More specifically, certain embodiments of the invention relate to a method and system for a high-density, low-cost, CMOS compatible memory.

### BACKGROUND

Complementary metal oxide semiconductor (CMOS) transistors are ubiquitous in today's electronics devices. Conventional memory circuits are often too big and/or too expensive.

Further limitations and disadvantages of conventional and traditional approaches will become apparent to one of skill in the art, through comparison of such systems with the present invention as set forth in the remainder of the present application with reference to the drawings.

### BRIEF SUMMARY

A system and/or method for improved analog performance in sub-100 nanometer CMOS transistors substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a diagram illustrating a single-bit memory, in accordance with an example embodiment of the disclosure.

FIG. 2 is a diagram illustrating an 8-bit memory cell, in accordance with an example embodiment of the disclosure.

FIG. 3A illustrates an example layout of an 8-bit memory cell per source follower, in accordance with an example embodiment of the disclosure.

FIG. 3B illustrates an example layout of an 8-bit memory cell per source follower, in accordance with an example embodiment of the disclosure.

FIG. 4 illustrates an alternative structure for a 16-bit memory cell, in accordance with an example embodiment of the disclosure.

FIG. 5 illustrates an example layout of an alternative structure involving two 16-bit per source follower memory cells, in accordance with an example embodiment of the disclosure.

FIG. 6 is a detailed view of transistors of a memory cell, in accordance with an example embodiment of the disclosure.

FIG. 7 illustrates an example layout for the storage capacitors of memory cells, in accordance with an example embodiment of the disclosure.

### DETAILED DESCRIPTION

Certain aspects of the disclosure may be found in a high-density, low-cost, CMOS compatible memory. Exemplary aspects of the invention may comprise a memory cell on a chip, the memory cell comprising: a plurality of capacitor/switch pairs , wherein for each pair comprising a switch and a capacitor, a source terminal of the switch is coupled to a gate terminal of the capacitor. The memory cell may also comprise a reset transistor, a biasing circuit, and a source follower. A drain terminal of each switch of said plurality of capacitor/switch pairs may be coupled to a floating node that couples a source terminal of the reset transistor and a gate terminal of the source follower. The plurality of capacitor/switch pairs may comprise complementary metal-oxide semiconductor (CMOS) transistors. The biasing circuit may be coupled to a source terminal of the source follower. Drain and source terminals of each of the switches of the plurality of capacitor/switch pairs may be coupled to ground. A number of the plurality of capacitor/switch pairs may indicate a number of bits in the memory. The biasing circuit may comprise a current mirror. A bit-line for the memory cell may be coupled to a source terminal of the source follower. The bit-line may comprise a metal trace. The plurality of capacitor/switch pairs may be formed symmetrically about the source follower and bias circuit on a chip in which the memory is integrated. A shallow implant layer may provide electrical isolation between capacitors of the plurality of capacitor/switch pairs.

As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “block” and “module” refer to functions than can be implemented in hardware, software, firmware, or any combination of one or more thereof. As utilized herein, the term “exemplary” means serving as a non-limiting example, instance, or illustration. As utilized herein, the term “e.g.,” introduces a list of one or more non-limiting examples, instances, or illustrations.

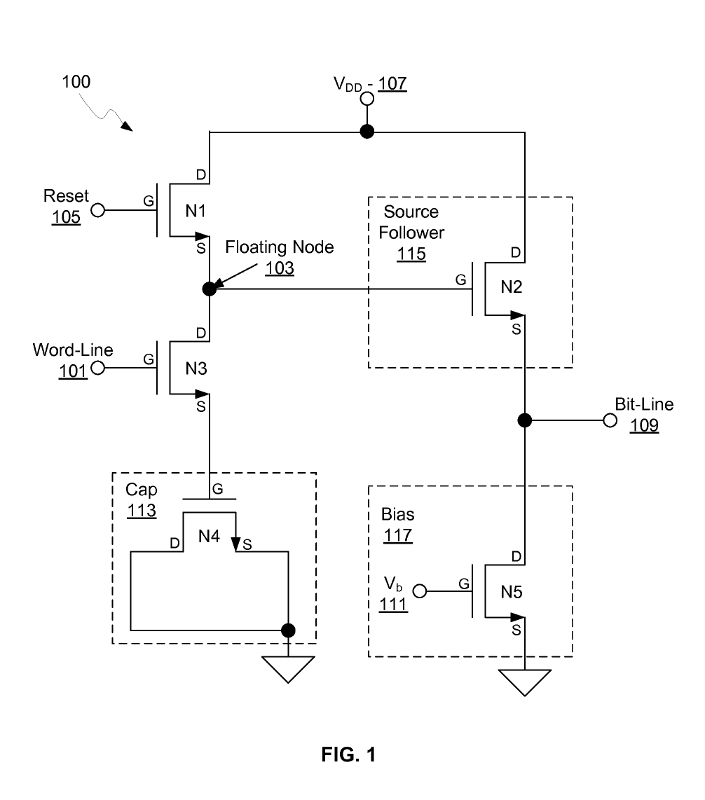

FIG. 1 is a diagram illustrating a single-bit memory, in accordance with an example embodiment of the disclosure. Referring to FIG. 1, there are shown a single-bit memory 100 comprising n-channel complementary metal-oxide semiconductor (CMOS) transistors N1-N5, a word-line 101, a floating node 103, a reset line 105, a supply voltage V_{DD} 107, an output or bit-line 109, and a bias line 111.

The CMOS transistors N1-N5 each serve different purposes, with N1 for receiving a reset signal, N2 as a source follower 115 for sensing voltage changes of the floating node 103, N3 for receiving the word-line signal, N4 having a coupled source and drain thereby forming a capacitor 113 for the switching capacitor N3, and N5 as a bias circuit 115 for supplying a current to the source follower 115.

The CMOS transistors N1-N5 comprise n-channel devices with a gate, source, and drain indicated by G, S, and D, respectively. The single-bit memory 100 may operate by writing and reading a bit by storing and reading a charge in the capacitor 113 comprising the drain-source coupled CMOS transistor N4. The bias control 115 may comprise n-channel CMOS transistor N5 with a bias voltage V_{b} at its gate terminal that may be configured to a desired, essentially constant current through the source follower 115.

To write a “0” to the single-bit memory 100, the supply voltage V_{DD} 107 may be set to 0 volts while the reset line 105 and the word-line 101 are asserted, which turns on CMOS transistors N1 and N3, respectively, thereby discharging any charge in the capacitor 113. To write a “1” to the single-bit memory 100, the supply voltage V_{DD} 107, reset line 105, and word-line 101 may be set high, e.g., 1.1V, such that the capacitor 113 is charged to the supply voltage V_{DD} 107, minus any drain-source drop across the CMOS transistors N1 and N3. The voltage on the reset line 105 may be set at a higher voltage, e.g., greater than 1.1V, to reduce the floating node 103 voltage drop.

For reading the single-bit memory 100, first a pre-charge of the floating node 103 may be performed by asserting the reset line 105 and setting supply voltage V_{DD} 107 to bring the floating node 103 to ˜½ V_{DD}, for example. Then, the reset line 105 may be de-asserted and the word-line 101 may be asserted, thereby coupling the capacitor 113 to the source follower 115 comprising CMOS transistor N2. If the single-bit memory 100 had recently been written to “1,” the floating node 103 may slightly increase due to the charge of the capacitor 113. Alternatively, if the single-bit memory 100 had been written to “0” the floating node 103 would drop due to the lack of charge in the capacitor 113.

The change in voltage of the floating node 103 may be sensed by the source follower 115, where the change in the gate voltage of the CMOS transistor N2 changes its drain-source current modifying the voltage at the bit-line 109. Due to the near-unity gain, the source follower 115 may act as a buffer for the floating node 103.

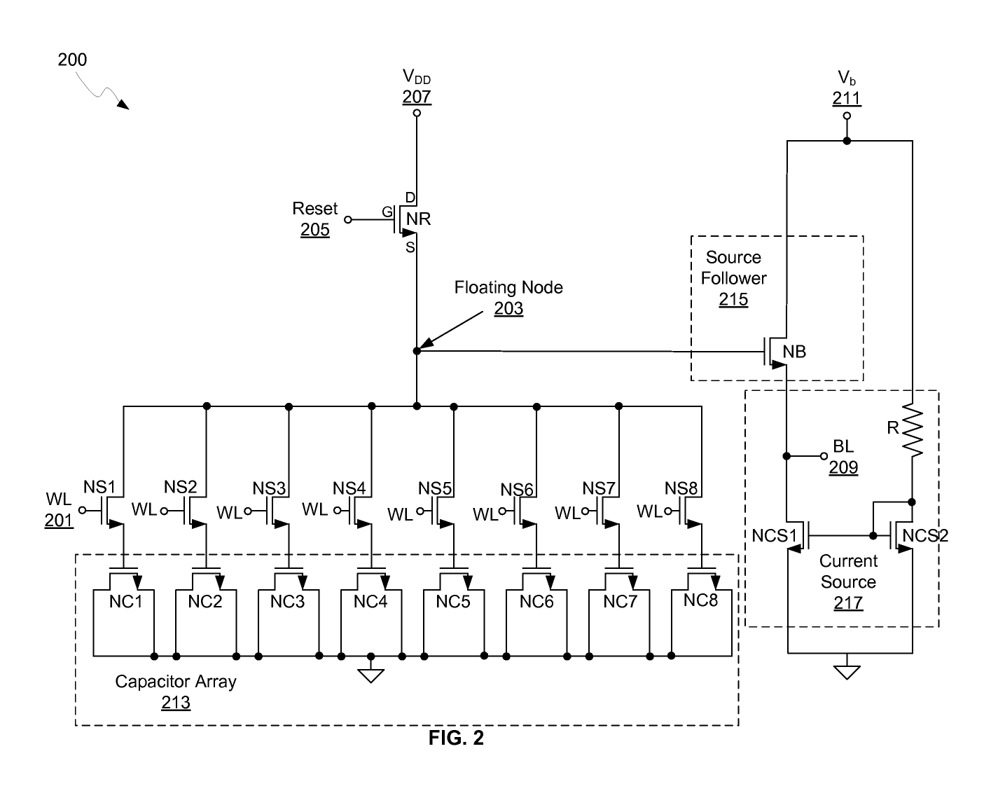

In an example scenario, the structure shown in FIG. 1 may be scaled to any number of CMOS transistor N3/N4 pairs with a single floating node, reset, bias control, and source follower, as shown in FIG. 2.

FIG. 2 is a diagram illustrating an 8-bit memory cell, in accordance with an example embodiment of the disclosure. Referring to FIG. 2, there are shown an 8-bit memory 800 comprising switching CMOS transistors NS1-NS8, a capacitor array 213, a CMOS reset transistor NR, a source follower 215, and current source 217. There are also shown word-lines 201, a floating node 203, reset line 205, supply voltage V_{DD} 207, bit-line 209, and bias supply voltage V_{b} 211. For figure clarity, the gate, source, and drain are not labeled for every CMOS transistor, but follow conventional nomenclature for n-channel MOSFETS.

The circuit in FIG. 2 is similar to that shown in FIG. 1, but with eight switching transistor/capacitor transistor pairs, which results in an 8-bit memory cell. The capacitor array 213 may comprise CMOS capacitor transistors NC1-NC8 with source and train terminals coupled together and to ground, thereby configuring an array of switchable CMOS capacitors. The source follower 215 comprises a floating node 213 sense transistor NB. The current source 217 may comprise a resistor R and CMOS transistors NCS1 and NCS2.

The eight capacitors in the example shown in FIG. 2 is equivalent to (8T+3T+8C)/(8 bit-cells)=(1.375T+1C)/bit-cell. Increasing to 16 switched capacitor cells in the capacitor array 213 sharing the same source follower 215 would lead to 1.1875T+1 cap/cell. This illustrates the scaling ability of the structure, where a large number of switched capacitor cells may be integrated in a cell with a single source follower output and bias circuit.

Each of the CMOS switching transistors NS1-NS8 may comprise a word-line input 201 at their respective gate terminals, with the drain terminals of each transistor coupled together at the floating node 203, and the source terminals coupled to the capacitor CMOS transistors NC1-NC8 of the capacitor array 213.

The CMOS transistors NCS1 and NCS2 with the resistor R may comprise a current mirror that provides a current for the sense transistor NB to keep the voltage difference between the floating node 203 and the bit-line near 209 constant. The output signal indicated by the voltage at the floating node 203 may be communicated to the bit-line (BL) 209, which comprises a metal trace instead of a diffused layer as used by traditional DRAM, where a metal trace reduces the parasitic resistance substantially and improves refresh rate.

The CMOS reset transistor NR may comprise the reset line 205 at its gate terminal, where a voltage at the gate activates the transistor, thereby coupling the supply voltage V_{DD} 207 to the floating node 203.

In an example scenario, switching CMOS transistors NS1-NS8 may have 40 nm gate lengths and 80 nm widths, while the capacitor CMOS transistors NC1-NC8 may comprise 180 nm gate length and 80 nm width. The supply voltage V_{DD} 207 may be set to 1.1 V for write operations and 0.55 V for read operations, the voltage applied to the reset line 205 may be 1.2 V, and 1.1V may be applied to the word-line 201.

As with the single-bit memory 100, the 8-bit memory 200 may be written to and read from with similar steps. Accordingly, to write a “0” to the 8-bit memory 200, the supply voltage V_{DD} 207 may be set to 0 volts while the reset line 205 and the appropriate word-line 201 corresponding to the desired bit are asserted, which turns on CMOS transistors NR and one of NS1-NS8, thereby discharging any charge in the capacitor NC1-NC8 coupled to the activated transistor NS1-NS8.

To write a “1” to the 8-bit memory 200, the supply voltage V_{DD} 207, reset line 205, and appropriate word-line 201 may be set high, e.g., 1.2V and 1.1V, respectively, such that the CMOS capacitor transistor coupled to the selected switching transistor NS1-NS8 is charged to the supply voltage V_{DD} 207, minus any drain-source drop across the CMOS transistors NR and the selected NS1-NS8. The voltage on the reset line 205 may be set at a higher voltage, e.g., 1.2V, to reduce the floating node 203 voltage drop.

For reading the 8-bit memory 200, first a pre-charge of the floating node 203 may be performed by asserting the reset line 205 and setting supply voltage V_{DD} 207 to bring the floating node 203 to ˜½ V_{DD}, for example. Then, the reset line 205 may be de-asserted and the word-line 201 of the desired switching transistor NS1-NS8 may be asserted, thereby coupling the CMOS capacitor transistor to the source follower 215 comprising CMOS transistor NB. If the bit being read had recently been written to “1,” the floating node 203 may slightly increase due to the charge of the capacitor NC1-NC8 being read. Alternatively, if the 8-bit memory 200 had been written to “0” the floating node 203 would drop due to the lack of charge in the capacitor NC1-NC8 being read.

The change in voltage of the floating node 203 may be sensed by the source follower 215, where the change in the gate voltage of the CMOS transistor NB changes its drain-source current, modifying the voltage at the bit-line 209. Due to the near-unity gain, the source follower 215 may act as a buffer for the floating node. In an example implementation, a simple comparator at the bit-line 209 is sufficient for detection.

Embedded DRAM is currently not available in advanced node CMOS technologies such as 28 nm. One transistor static random-access memory (1T SRAM) is limited by high leakage power, and is not available in 40 nm and below technology nodes. In an example scenario, the structure shown in FIG. 2 results in a more area-efficient and cost-effective RAM compared to existing standard 28 nm 6T SRAM, which may result in a reduction of more than 50% in memory area. FIG. 2 illustrates a CMOS process compatible DRAM bit-cell structure. Averaging less than 1.187 transistor+1 cap/bit-cell, which is approaching traditional DRAM 1T+1 C/bit-cell. In addition, the structure may be scaled to large memory array size. For example, 16-shared bit-cell layout area is equivalent to only ½ the size of a 28 nm SRAM bit-cell, thereby reducing the area by 50%.

The sensing from the bit-line 209 may utilize a double sampling technique for signal readout. The use of the CMOS transistor NB configured as a source follower buffer enables easy sensing without relying on extremely sensitive sense amps (SA) used in traditional DRAM. Bit-cell refresh and readout rate may be much higher than traditional 1T-1C DRAM due to the much lower parasitic resistance in the bit-line 209.

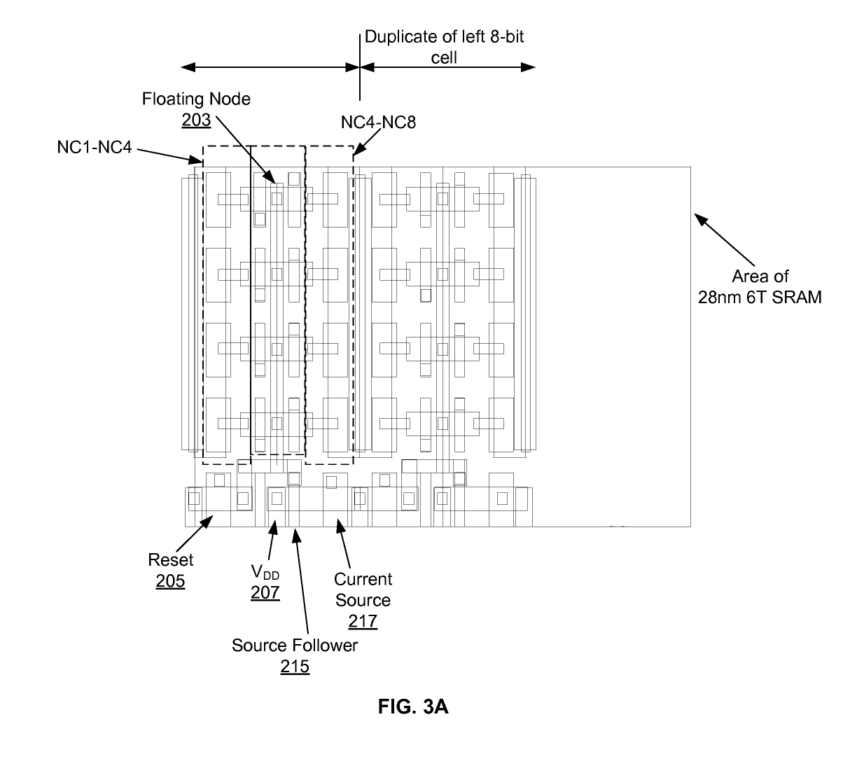

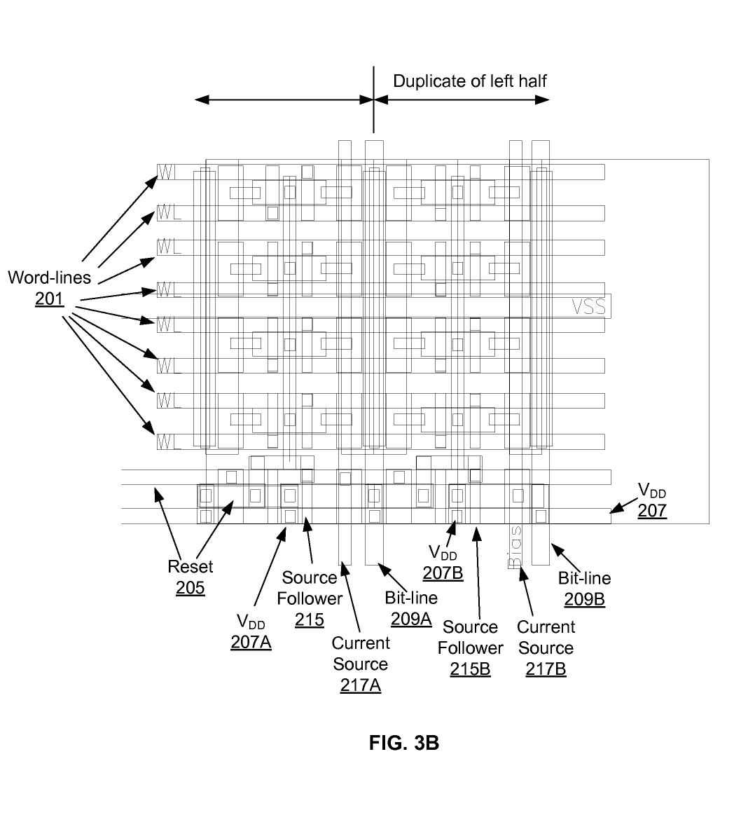

FIG. 3A illustrates an example layout of an 8-bit memory cell per source follower, in accordance with an example embodiment of the disclosure. Referring to FIG. 3A, there are shown two duplicate sections of eight switched capacitor cells, with the left side labeled, showing the CMOS capacitors NC1-NC8.

The outline around the two 8-bit sections indicates the area needed for a 16-bit 6T SRAM cell in a 28 nm CMOS node, where a 24-bit section may fit using the structure disclosed here, demonstrating the 33% area savings of this structure.

In another example scenario, both of the eight capacitor CMOS transistors NC1-NC8 shown in FIG. 3A, could share the reset, source follower, and bias circuits in the center by coupling to two more sets of 8-bit sections comprising capacitor CMOS transistors arranged symmetrically below the reset line 205, V_{DD} supply 207, source follower 215, and current source 217.

FIG. 3B illustrates an example layout of an 8-bit memory cell per source follower, in accordance with an example embodiment of the disclosure. Referring to FIG. 3B, there is shown the structure of FIG. 3A, with metal layer added showing interconnections to the word-lines 201, the bit lines 209A and 209B, the reset line 205, and V_{DD} supply line 207. There is also shown a common connection V_{SS}, which may comprise the ground connection to the capacitor CMOS transistors. Alternatively, a DC voltage may be applied to V_{SS} instead of ground.

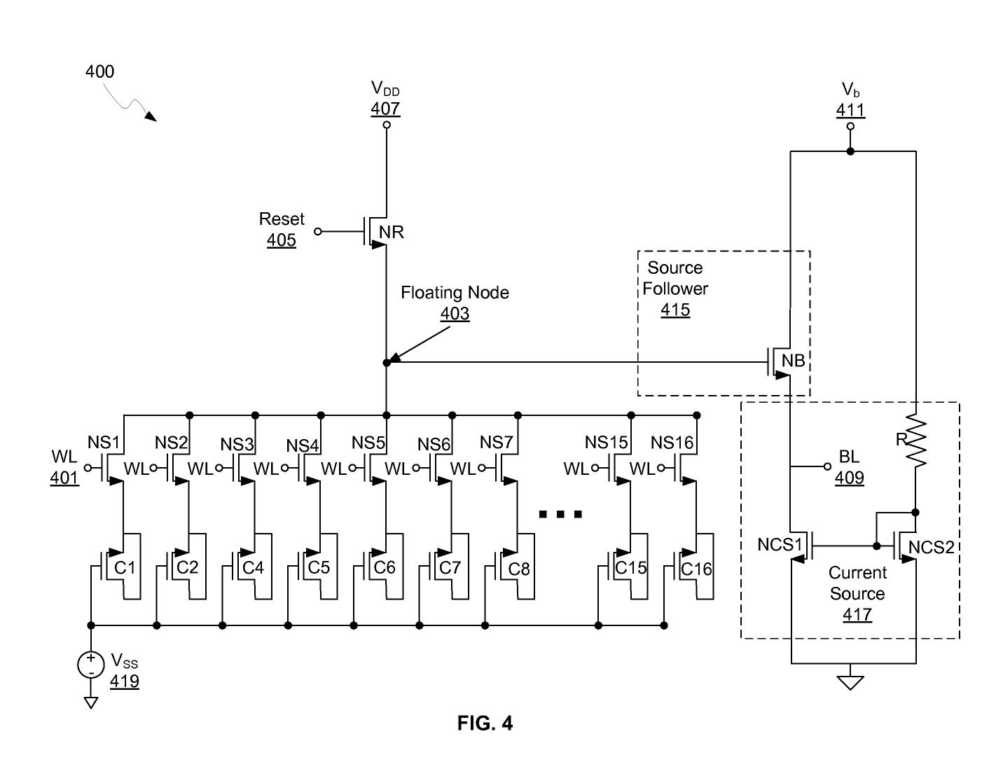

FIG. 4 illustrates an alternative structure for a 16-bit memory cell, in accordance with an example embodiment of the disclosure. Referring to FIG. 4, there are shown a 16-bit memory 400 comprising switching transistors NR, NS1-NS16, CMOS capacitors C1-C16, source follower 415, and current source 417. There are also shown word lines 401, floating node 403, reset line 405, V_{DD} supply 407, bit-line 409, bias voltage V_{b} 411, and supply voltage V_{SS} 419.

As described in FIGS. 1 and 2, the capacitors C1-C16 may comprise CMOS transistors with their source and drain terminals coupled together, and their gates coupled to the supply voltage V_{SS} 419.

In an example scenario, switching CMOS transistors NS1-NS16 and source followed and biasing CMOS transistors may have 80 nm gate widths and 50 nm lengths, while the capacitor CMOS transistors C1-C16 may comprise 180 nm gate widths and 50 nm lengths. In another example scenario, all the CMOS transistors may have the same width/length, such as 80 nm/ 50 nm. Utilizing smaller sized CMOS transistors for all devices in the 16-bit memory reduces the area required. The supply voltage V_{DD} 407 may be set to 1.1 V for write operations and 0.7 V for read operations, the voltage applied to the reset line 405 may be 1.2 V, and 1.1V may be applied to the word-line 401.

As with the single-bit memory 100 and the 8-bit memory 200, the 16-bit memory 400 may be written to and read from with similar steps. Accordingly, to write a “0” to the 16-bit memory 400, the supply voltages V_{DD} 407 and V_{SS} 419 may be set to 0 volts while the reset line 405 and the appropriate word-line 401 corresponding to the desired bit are asserted, which turns on CMOS transistors NR and one of NS1-NS16, thereby discharging any charge in the capacitor C1-C16 coupled to the activated transistor NS1-NS16.

To write a “1” to the 16-bit memory 400, the supply voltage V_{DD} 407, reset line 205, and appropriate word-line 201 may be set high, e.g., 1.2V and 1.1V, respectively, such that the CMOS capacitor C1-C16 coupled to the selected switching transistor NS1-NS16 is charged to the supply voltage V_{DD} 407 plus the supply voltage V_{SS} 419, minus any drain-source drop across the CMOS transistors NR and the selected NS1-NS16. The voltage on the reset line 405 may be set at a higher voltage, e.g., 1.2V, to reduce the floating node 403 voltage drop.

For reading the 16-bit memory 400, first a pre-charge of the floating node 403 may be performed by asserting the reset line 405 and setting supply voltage V_{DD} 407 to bring the floating node 403 to ˜½ V_{DD}, for example. Then, the reset line 405 may be de-asserted and the word-line 401 of the desired switching transistor NS1-NS16 may be asserted, thereby coupling the CMOS capacitor C1-C16 to the source follower 415 comprising CMOS transistor NB. If the bit being read had recently been written to “1,” the floating node 403 may slightly increase due to the charge of the capacitor C1-C16 being read. Alternatively, if the 8-bit memory 200 had been written to “0” the floating node 403 would drop due to the lack of charge in the capacitor C1-C16 being read.

The change in voltage of the floating node 403 may be sensed by the source follower 415, where the change in the gate voltage of the CMOS transistor NB changes its drain-source current, modifying the voltage at the bit-line 409. Due to the near-unity gain, the source follower 415 may act as a buffer for the floating node. In an example implementation, a simple comparator at the bit-line 409 is sufficient for detection. The alternative embodiment shown in FIG. 4 is more compact than that shown in FIG. 2, with a 50% improvement in area usage over conventional 28 nm 6T SRAM.

With a 16-bit cell per source follower configuration, each capacitor may be about 20-25% of the floating node capacitance. While the floating node may be leaky with abrupt junctions in CMOS transistors, this may be mitigated with an implant profile change without using additional masks. Furthermore, reduction of the floating node parasitic capacitance using a metal trace further improves sensitivity and increases the number of capacitor cells that can be sensed by each source follower device, leading to higher efficiency.

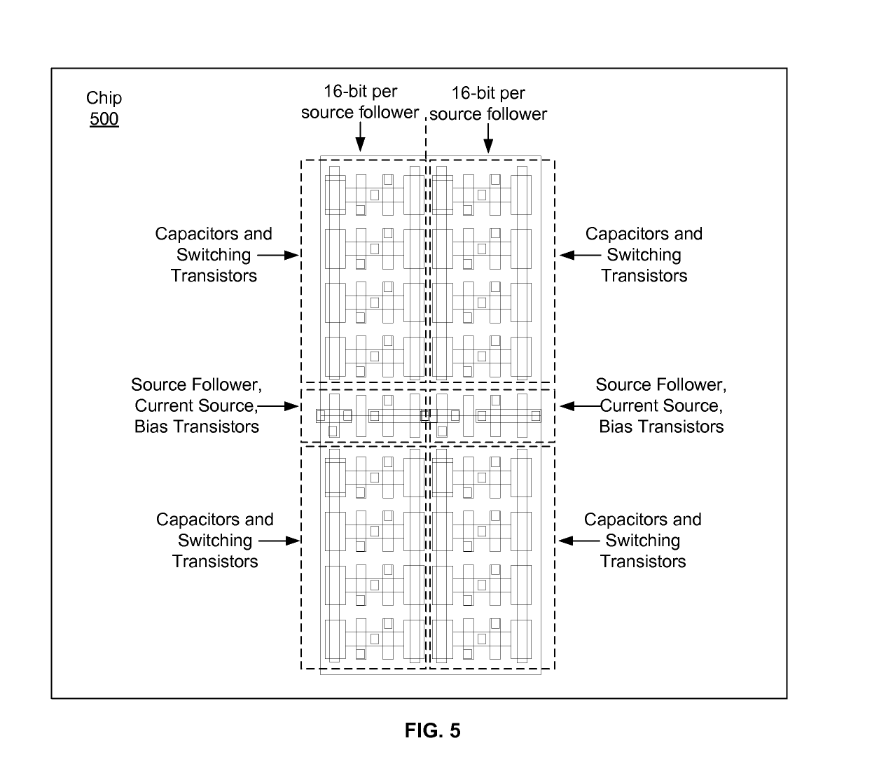

FIG. 5 illustrates an example layout of an alternative structure involving two 16-bit per source follower memory cells, in accordance with an example embodiment of the disclosure. Referring to FIG. 5, there are shown symmetric sections of CMOS capacitors and switching transistors surrounding a center section comprising source follower, a current source, and bias transistors, all integrated on an integrated circuit, or chip 500. The chip 500 may comprise a die separated from a silicon or silicon-on-insulator (SOI) wafer processed using CMOS processes to form electronics circuitry, including the memory cell formed from the CMOS capacitors and switching transistors, the source follower, current source, and bias transistors. The center section is coupled to both of the symmetric sections of CMOS capacitors and switching transistors, and illustrates a 16-bit per source follower configuration.

In an example scenario with 80/50 nm W/L transistors and 160 nm/50 nm for MOS capacitors, the total area of this 32-bit memory cell utilizes an area of under 2 μm², which is equal to a 16-bit 6T SRAM, illustrating the 50% area efficiency improvement of the structure while still being compatible with standard CMOS processes. This enables efficient and high packing density that is also scalable for variable-cell construction.

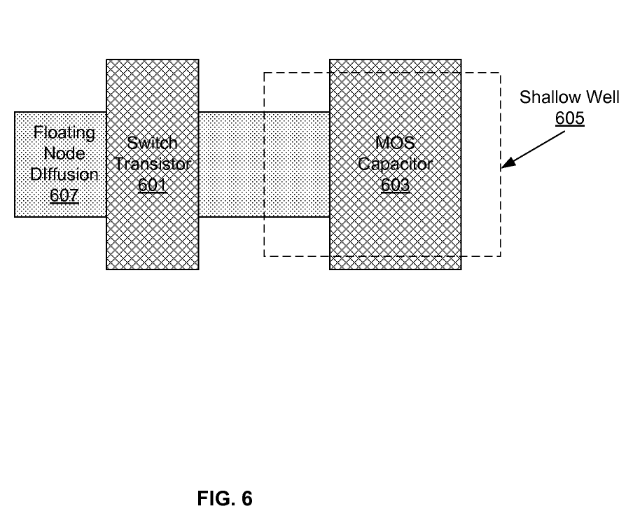

FIG. 6 is a detailed view of transistors of a memory cell, in accordance with an example embodiment of the disclosure. Referring to FIG. 6, there are shown a switch transistor 601, a MOS capacitor 603, a shallow well implant 605, and a floating node diffusion 607. The MOS capacitor may be based on n+ polysilicon on an N-well MOS varactor scheme, although other implementations may use other schemes for realizing the capacitor. In an example implementation, salicidation blocking may be used for reducing leakage current as shown by the floating node diffusion 607 in FIG. 6, since the diffusion region connecting the switch transistor 601 (e.g., N3 in FIG. 1) and the MOS capacitor 603 is important for charge retention. Salicidation may be avoided for this region by using salicide block (SAB).

Because the traditional abrupt shallow junction for the switch transistor 601 (n+ on Pwell for NFET) may be leaky for the leakage-sensitive diffusion region, it may be modified by changing the regular n+ source/drain implant. Since there is no high current flowing through this region (only charging and discharging the cap), the n+ implant dose may be reduced to make it less abrupt in forming the shallow well 605. One example is to utilize the same I/O n-type lightly doped drain (NLDD) implant mask which has much less implant dose (n−) without using pocket implant (p-type) to implant it after poly formation. An N+ implant can be blocked off here.

In an example implementation, floating node diffusion 607 leakage may not be critical where the read/write time is very short and does not result in much charge loss. Accordingly, there may not be a need for a salicidation block or implant engineering for the floating node diffusion 607.

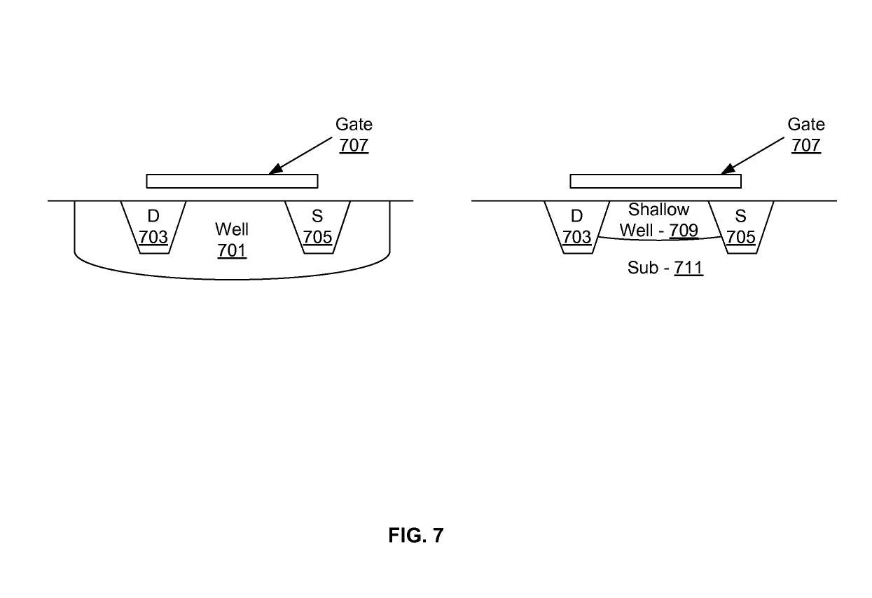

FIG. 7 illustrates a layout for the storage capacitors of memory cells, in accordance with an example embodiment of the disclosure. Referring to FIG. 7, a vertical cut cross-section of the capacitor shown in FIG. 6 is shown with well 701, drain 703, source 705, and gate 707. In order to make an isolated MOS capacitor, such as an n+ poly on Pwell or varactor comprising n+ polysilicon on Nwell, to serve as a charge storage cell, an extra shallow implant layer, such as the shallow well implant layer 709, may be formed before polysilicon formation in order to be isolated from neighboring cells. Traditional well implant, such as in forming the well 701, is deeper than shallow trench isolation (STI) and may not provide isolation between two MOS capacitors next to each other. A shallower well implant 709 may be used and the underneath Pwell (same well from the switch NFET) combined with shallow trench isolation may serve as good electrical isolation from neighboring capacitor of the same type.

In an embodiment of the disclosure, a method and system may comprise a memory cell on a chip, the memory cell comprising: a plurality of capacitor/switch pairs, where for each pair comprising a switch and a capacitor, a source terminal of the switch is coupled to a gate terminal of the capacitor. The memory cell also may comprise a reset transistor, a biasing circuit, and a source follower. A drain terminal of each switch of said plurality of capacitor/switch pairs may be coupled to a floating node that couples a source terminal of the reset transistor and a gate terminal of the source follower. The plurality of capacitor/switch pairs may comprise complementary metal-oxide semiconductor (CMOS) transistors.

The biasing circuit may be coupled to a source terminal of the source follower. Drain and source terminals of each of the switches of the plurality of capacitor/switch pairs may be coupled to ground. A number of the plurality of capacitor/switch pairs may indicate a number of bits in the memory. The biasing circuit may comprise a current mirror. A bit-line for the memory cell may be coupled to a source terminal of the source follower. The bit-line may comprise a metal trace. The plurality of capacitor/switch pairs may be formed symmetrically about the source follower and bias circuit on a chip in which the memory is integrated. A shallow implant layer may provide electrical isolation between capacitors of the plurality of capacitor/switch pairs.

Other embodiments may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for a high-density, low-cost, CMOS compatible memory.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A semiconductor device, the device comprising:
a memory cell on a chip, the memory cell comprising:
a plurality of capacitor/switch pairs, wherein for each pair comprising a switch and a capacitor, a source terminal of the switch is coupled to a gate terminal of the capacitor;
a reset transistor;
a biasing circuit; and
a source follower, wherein a drain terminal of each switch of said plurality of capacitor/switch pairs is coupled to a floating node that couples a source terminal of the reset transistor and a gate terminal of the source follower.

2. The device according to claim 1, wherein the plurality of capacitor/switch pairs comprise complementary metal-oxide semiconductor (CMOS) transistors and MOS capacitors.

3. The device according to claim 1, wherein the biasing circuit is coupled to a source terminal of the source follower.

4. The device according to claim 1, wherein drain and source terminals of each of the switches of the plurality of capacitor/switch pairs is coupled to ground.

5. The device according to claim 1, wherein a number of said plurality of capacitor/switch pairs indicates a number of bits in the memory.

6. The device according to claim 1, wherein the biasing circuit comprises a current mirror.

7. The device according to claim 1, wherein a bit-line for the memory cell is coupled to a source terminal of the source follower.

8. The device according to claim 7, wherein the bit-line comprises a metal trace.

9. The device according to claim 1, wherein the plurality of capacitor/switch pairs are formed symmetrically about the source follower and bias circuit on a chip in which the memory is integrated.

10. The device according to claim 1, wherein a shallow implant layer provides electrical isolation between capacitors of the plurality of capacitor/switch pairs.

11. A semiconductor device comprising:
a memory cell on a chip, the memory cell comprising:
a plurality of capacitor/switch pairs, wherein for each pair comprising a switch and a capacitor, a source terminal of the switch is coupled to source and drain terminals of the capacitor;
a reset transistor;
a biasing circuit; and
a source follower, wherein a drain terminal of each switch of said plurality of capacitor/switch pairs is coupled to a floating node that couples a source terminal of the reset transistor and a gate terminal of the source follower.

12. The device according to claim 11, wherein the plurality of capacitor/switch pairs comprise complementary metal-oxide semiconductor (CMOS) transistors and MOS capacitors.

13. The device according to claim 11, wherein the biasing circuit is coupled to a source terminal of the source follower.

14. The device according to claim 11, wherein a gate terminal of each of the switches of the plurality of capacitor/switch pairs is coupled to a supply voltage.

15. The device according to claim 11, wherein a number of said plurality of capacitor/switch pairs indicates a number of bits in the memory.

16. The device according to claim 11, wherein the biasing circuit comprises a current mirror.

17. The device according to claim 11, wherein a bit-line for the memory is coupled to a source terminal of the source follower.

18. The device according to claim 17, wherein the bit-line comprises a metal trace.

19. The device according to claim 11, wherein the plurality of capacitor/switch pairs are formed symmetrically about the source follower and bias circuit on a chip in which the memory is integrated.

20. A semiconductor device comprising:
a 16-bit memory on a chip, the memory comprising:
a plurality of capacitor/switch pairs, wherein for each pair comprising a switch and a capacitor, a source terminal of the switch is coupled to source and drain terminals of the capacitor;
a reset transistor;
a biasing circuit; and
a source follower, wherein an area of the 16-bit memory cell is less than 2 μm² and utilizes 1.1875 transistor+1 capacitor or less per cell of the memory.
